(19) United States
(12) Patent Application Publication
(10) Pub. No.: US 2024/0283223 A1
(43) Pub. Date: Aug. 22, 2024

(54) Heating station comprising a laser emitter

(71) Applicant: SIDEL PARTICIPATIONS, OCTEVILLE-SUR-MER (FR)

(72) Inventors: Guy FEUILLOLEY, OCTEVILLE-SUR-MER (FR); Laurent DANEL, OCTEVILLE-SUR-MER (FR); Anthony LE PECHOUR, OCTEVILLE-SUR-MER (FR); Nicolas CHOMEL, OCTEVILLE-SUR-MER (FR)

(21) Appl. No.: 18/567,767

(22) PCT Filed: Jun. 9, 2022
(86) PCT No.: PCT/EP2022/065725

§ 371 Date: Dec. 6, 2023

(30) Foreign Application Priority Data
Jun. 9, 2021 (FR) FR2106061

(51) Int. Cl. H01S 5/42; H01S 5/024; H01S 5/042; H01S 5/34

(52) U.S. Cl. CPC H01S 5/423; H01S 5/02469; H01S 5/042; H01S 5/34

(57) ABSTRACT

A heating station of a container manufacturing installation, the heating station having a plurality of laser emitters wherein each laser emitter includes a plurality of laser chips mounted on an external face of at least one support. In example embodiments, each laser chip includes at least one laser diode arranged to emit laser radiation in the infrared range in an emission direction substantially perpendicular to the external face of the support. In example embodiments, each laser diode includes at least two active regions stacked on one another in the emission direction, wherein each active region participating in the laser radiation emitted by said laser diode.

The present invention relates to a laser emitter for a heating station of a container manufacturing installation, of the type comprising a plurality of laser chips mounted on an external face of at least one support, each laser chip comprising at least one laser diode arranged to emit laser radiation in the infrared range in an emission direction substantially perpendicular to the external face of the support.

The invention also relates to a heating station of a container manufacturing installation, comprising a plurality of such laser emitters.

Such a heating station, or furnace, is equipped with a succession of laser emitters of which the laser chips are arranged to emit laser radiation in the infrared range in the direction of preforms made from synthetic material traveling through the heating station while rotating on themselves, in order to apply a heating profile to these preforms and allow their subsequent deformation, for example by stretch blow molding, so as to produce containers from the preforms. Each laser chip comprises a plurality of laser diodes emitting the desired laser radiation. Such laser diodes are in particular vertical cavity surface emitting laser (VCSEL) diodes.

In order to apply the desired heating profile to the entire height of a preform, a plurality of emitters are disposed one above the other in an elevation direction corresponding to the height of the preforms. Furthermore, in order to adequately heat an entire preform, emitters are provided next to one another along the entire trajectory of travel of the preforms through the heating station and possibly facing one another on either side of the preforms. Thus, a heating station comprises a large number of laser emitters each comprising a large number of laser chips.

Such numbers complicate the manufacture and assembly of the laser emitters, requiring a large number of electrical cable connection operations in order to supply the laser emitters with electricity. Furthermore, the operation of the laser emitters involves significant electrical consumption, especially since relatively significant electrical losses take place through the Joule effect in the electrical cables.

One of the aims of the invention is to overcome these drawbacks by proposing a heating station comprising a plurality of laser emitters of which the manufacture and assembly are simplified and of which the electrical consumption can be reduced, while at the same time limiting the electrical losses.

To this end, the invention relates to a heating station of a container manufacturing installation, comprising a plurality of laser emitters of the abovementioned type, wherein each laser diode comprises at least two active regions stacked on one another in the emission direction, each active region participating in the laser radiation emitted by said laser diode.

By using such laser diodes in the laser chips of the emitter, it is possible to reduce the number of chips required to obtain laser radiation equivalent to that of conventional laser emitters, of which the laser diodes each comprise a single active region. Thus, the manufacture of a laser emitter is simplified and likewise its assembly in a heating station. The number of electrical wiring operations is also reduced. Furthermore, the laser chips used in the laser emitter according to the invention can operate at a current of lower intensity, and this improves the efficiency of the heating station by reducing the electrical consumption and limiting the electrical losses through the Joule effect. Moreover, this lower current also increases the lifetime of the laser diodes used in the laser chips.
The laser emitter according to the invention may also comprise one or more of the following features, considered in isolation or in any technically conceivable combination:
each laser diode is a vertical cavity surface emitting laser diode, each active region being a quantum well junction extending in a direction substantially perpendicular to the emission direction and substantially parallel to the external face of the support;
the laser radiation is emitted through an active opening of each laser diode, said active opening extending substantially parallel to the external face of the support and having a diameter substantially between 5 μm and 25 μm;
the laser radiation emitted by each laser diode has a wavelength substantially between 1120 nm and 1140 nm;
each laser diode comprises three active regions stacked on one another in the emission direction, each active region participating in the laser radiation emitted by said laser diode;
each laser chip has an irradiation optical power density substantially between 1 and 20 W·mm²;
the laser emitter comprises between five and sixty laser chips, said laser chips being arranged in at least one row comprising a plurality of laser chips that are adjacent to one another in a longitudinal direction substantially perpendicular to the emission direction;
the laser emitter comprises a cooling device arranged on an inner face of the support, which is opposite the external face of the support, said support being made from a material that is thermally conductive, so as to allow the laser chips to be cooled by the cooling device, and electrically insulating;
the laser chips are supplied with electric current, said electric current having an intensity substantially less than or equal to 10 A, preferably less than or equal to 8 A.

According to another aspect, the invention relates to a container manufacturing installation having a heating station that comprises a plurality of laser emitters as described above, said laser emitters being distributed in an elevation direction corresponding to the height of preforms intended to be formed into containers in the manufacturing installation and in a longitudinal direction corresponding to a direction of travel of the preforms through the heating station facing the laser emitters.

Other aspects and advantages of the invention will become apparent upon reading the following description, which is given by way of example and with reference to the appended drawings, in which:

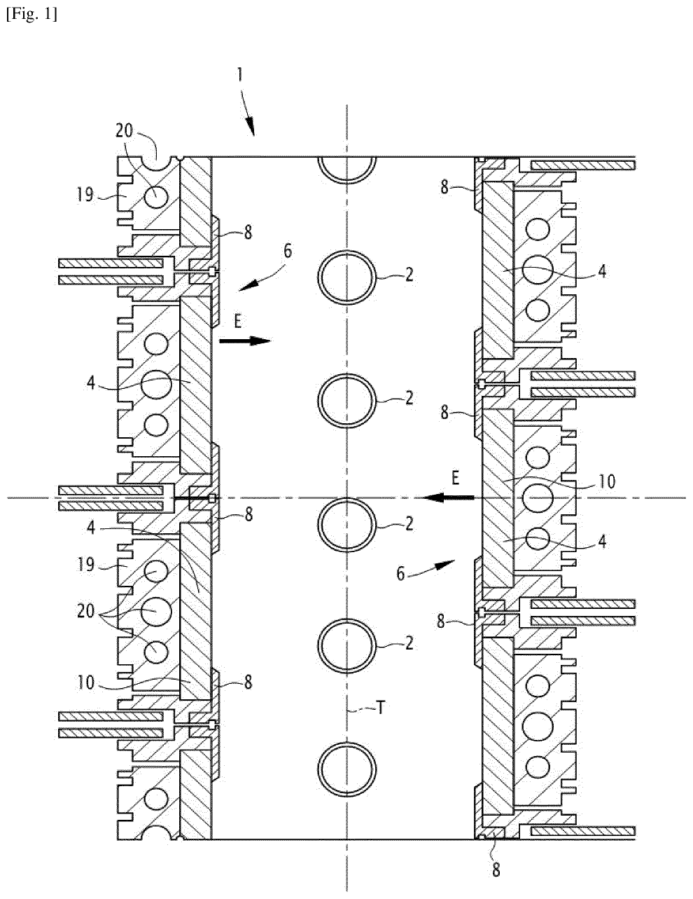

FIG. 1 is a schematic depiction in cross section of a part of a heating station comprising a plurality of laser emitters according to the invention,

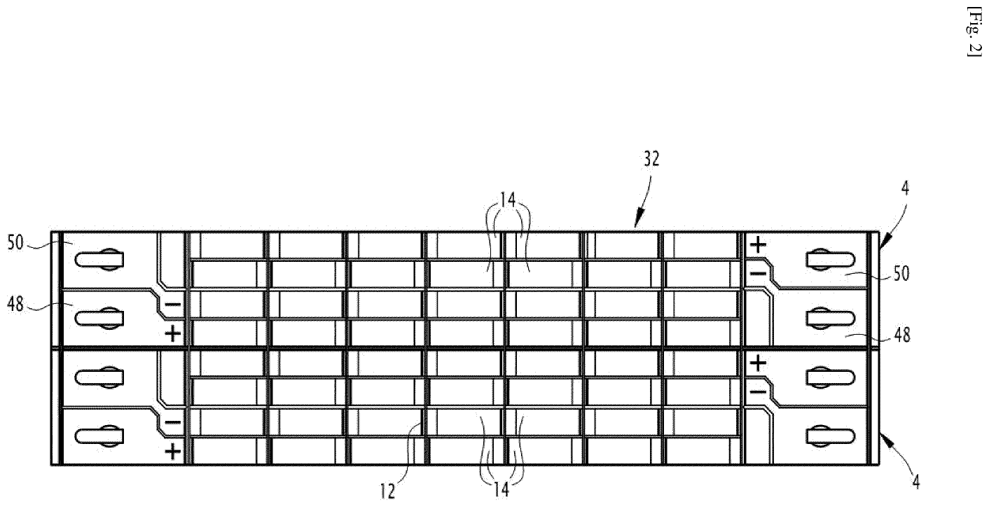

FIG. 2 is a schematic depiction from the front of two laser emitters according to the invention,

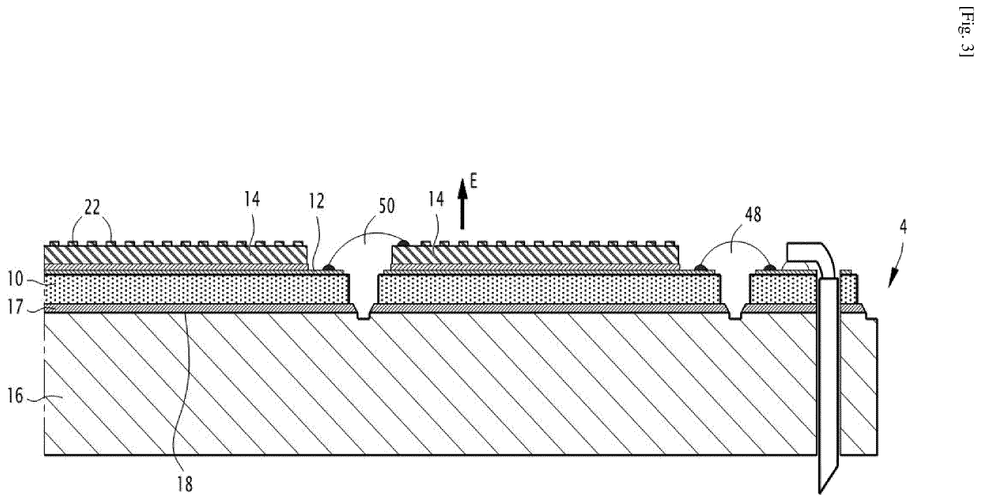

FIG. 3 is a schematic depiction in cross section of an emitter according to the invention,

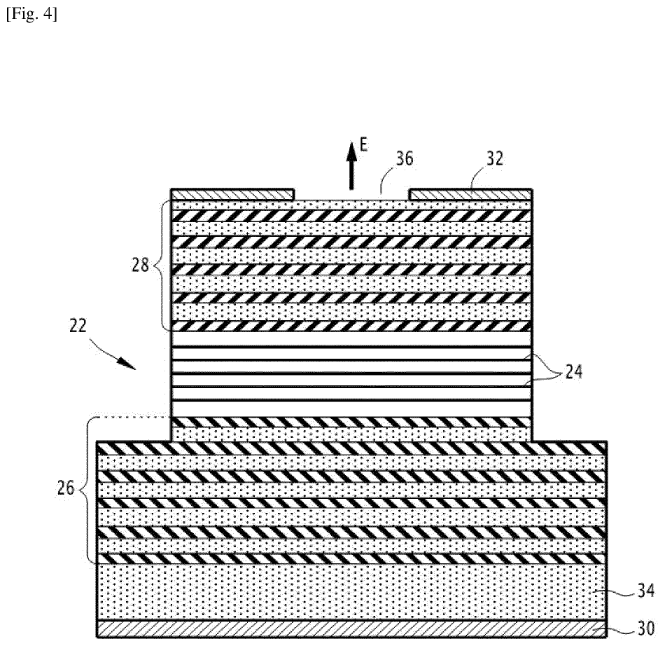

FIG. 4 is a schematic depiction in cross section of a laser diode used in a laser emitter according to the invention,

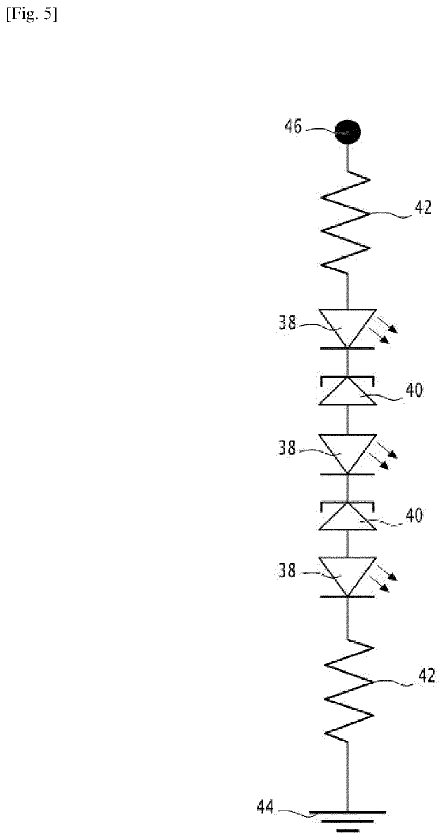

FIG. 5 is a schematic depiction of the equivalent electrical circuit of the laser diode in FIG. 4,

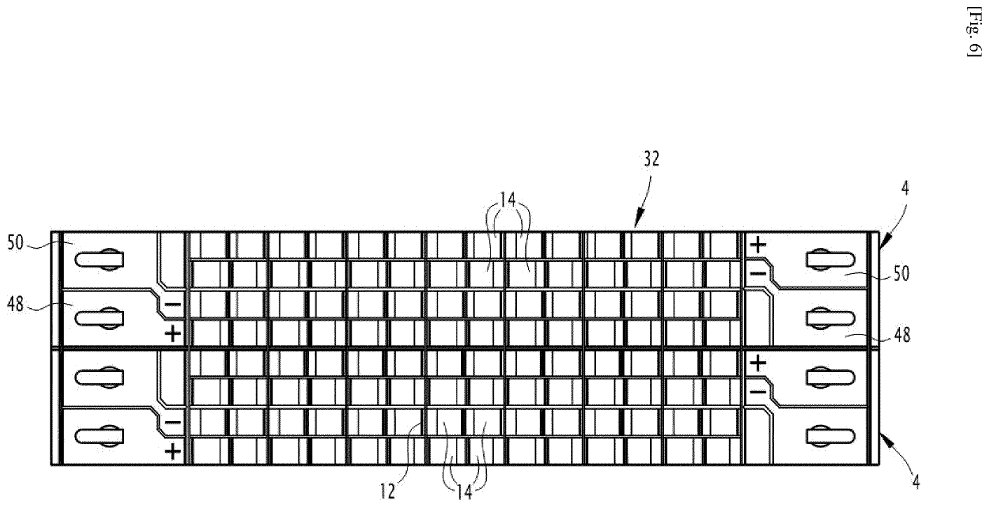

FIG. 6 is a schematic depiction from the front of two laser emitters according to the prior art, and

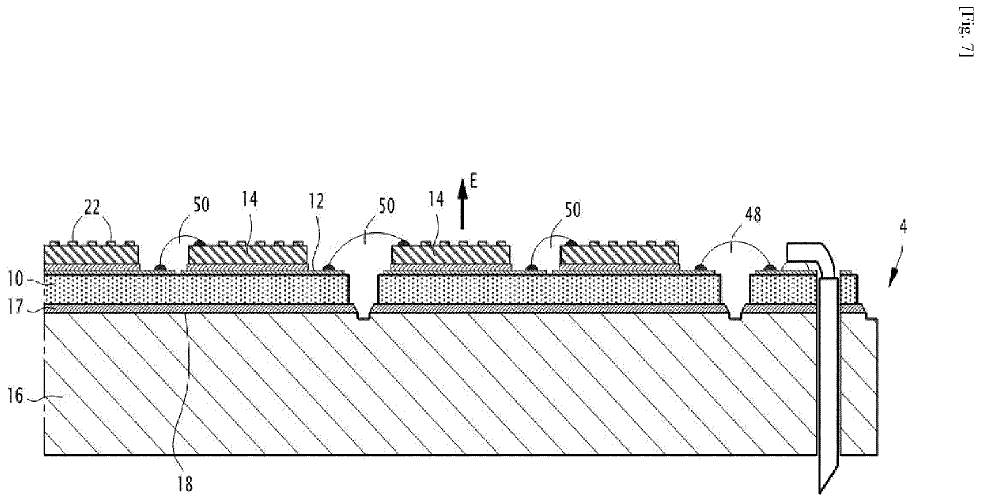

FIG. 7 is a schematic depiction in cross section of an emitter according to the prior art.

With reference to FIG. 1, a heating station 1, or furnace, of an installation for manufacturing containers from preforms 2, comprising a plurality of laser emitters 4, is described.

The heating station 1 comprises two walls 6 formed in particular by the laser emitters 4, the walls 6 being opposite one another on either side of the heating station 1. The walls 6 define an enclosure between them, within which the preforms 2 travel along a circulation path T defining a longitudinal direction. The walls 6 are spaced apart from one another in a transverse direction substantially perpendicular to the longitudinal direction so as to extend on either side of the circulation path T. In FIG. 1, the path T has been depicted as rectilinear, but it is understood that it could be curved in certain areas depending on the configuration of the container manufacturing installation. The heating station comprises a system (which is not depicted) for gripping and moving the preforms 2 along the circulation path T between the walls 6. The preforms 2 are more particularly held such that their respective axes extend in an elevation direction substantially perpendicular to the longitudinal direction and to the transverse direction. In other words, the elevation direction corresponds to the height of the preforms 2 and to the height of the walls 6. In a known manner, the gripping system can be arranged so that the preforms 2 rotate about their axis when they circulate along the path T.

The walls 6 simultaneously emit laser radiation, by way of the laser emitters 4 as will be described below, and reflect the radiation, for example by way of reflectors 8, which also form the walls 6 and extend between columns of emitters 4. Thus, for each wall, the laser emitters 4 are disposed one above the other in the elevation direction in columns such that the entire height of the preforms, with the exception of their neck, can be exposed to the radiation emitted by the emitters. In FIG. 2, two laser emitters 4 have been depicted one above the other in the elevation direction. Columns of emitters 4 are disposed next to one another in the longitudinal direction such that the preforms are exposed to the radiation along the entire circulation path T.

Such a heating station arrangement is known per se and will not be described in greater detail here.

All the laser emitters 4 of the heating station 1 are for example similar and one of them will now be described with reference to FIGS. 2 and 3.

The laser emitter 4 comprises at least one support 10, of which an external face 12 receives laser chips 14, as depicted in FIG. 2. The external face 12 of the support 10 extends facing the circulation path T such that the radiation emitted by the laser chips 14 is directed toward the preforms 2, as will be described in greater detail below. Generally, the laser emitter comprises a plurality of supports 10 each receiving a plurality of laser chips 14.

A cooling device 16, also known by the term “microcooler”, is mounted on the internal face 18 of the support 10, which is opposite the external face 12, i.e. the internal face 18 extends on the outside of the enclosure. The supports 10 are, for example, welded to the cooling device 16 by a layer of solder 17, as depicted in FIG. 3. The cooling device 16 is arranged to cool the laser chips 14 extending on the other side of the support 10 on the external face 12. The cooling device 16 is mounted on a cold plate 19 comprising, for example, ducts 20 for providing and discharging a heat-transfer fluid, as is known per se and as depicted in FIG. 1, in order to cool the cooling device 16, which in turn cools the laser chips 14.

In order to allow exchanges of heat between the cooling device 16 and the laser chips 14 and in order to allow the laser chips 14 to be satisfactorily electrically insulated from one another, the support 10 is made from a material having good thermal conduction and electrical insulation properties, such as ceramic for example.

The laser chips 14 are disposed on the support 10 in a row next to one another in the longitudinal direction. Each laser emitter 4 comprises at least one row of laser chips 14. According to one embodiment, the laser emitter 4 comprises, for example, two rows of laser chips 14 disposed on the external face 12 one above the other in the elevation direction. It is understood that more than two rows may be provided depending on the size of the laser emitter 4. It is also understood that other arrangements of laser chips on the support 10 may be envisaged, the arrangement depicted in FIG. 2 being given solely by way of nonlimiting example. A laser emitter 4 comprises for example between five and sixty laser chips, for example between five and thirty laser chips distributed over two rows or between ten and sixty laser chips distributed over four rows. As will be described in greater detail below, by virtue of the performance of each laser chip, it is possible to reduce the number of laser chips 14 per laser emitter 4 compared with conventional laser emitters and thus to make it easier to assemble the laser emitter 4 and its connections, as can be seen by comparing FIG. 2 and FIG. 6, which depicts two laser emitters of the prior art. In FIG. 6, the numerical references identical to those in FIG. 2 denote the same elements.

As depicted in FIG. 3, each laser chip 14 comprises at least one laser diode 22 arranged to emit laser radiation in the infrared range. More particularly, the wavelength of the laser radiation emitted by a laser diode 22 is substantially between 1120 nm and 1140 nm, for example substantially equal to 1130 nm. Such a wavelength is adapted so as to heat the material of the preforms 2 to a temperature higher than the glass transition temperature of this material in order to allow the subsequent deformation of the preforms so as to form containers after the preforms have passed through the heating station 1. Such a material is, for example, polyethylene terephthalate (PET). The laser radiation emitted by the laser diode 22 is directed in an emission direction E, which is for example substantially perpendicular to the external face 12 of the support 10 on which the laser chip 14 is installed, as depicted in FIG. 3. When the laser emitter 4 is installed in a heating station, the emission direction E is oriented toward the preforms 2 circulating through the heating station 1 and toward the wall 6 opposite the wall 6 bearing this laser emitter 4, as depicted in FIG. 1. According to one embodiment, each laser chip 14 comprises a plurality of laser diodes 22, for example so that each laser chip 14 has an irradiation optical power density substantially between 1 and 20 W·mm², more particularly for example between 1 and 5 W·mm². Such an irradiation optical power density is for example obtained by a laser chip 14 comprising between one thousand and two thousand five hundred laser diodes 22 depending on the size of the laser diodes 22.

A laser diode 22 used in a laser emitter 4 according to the invention will now be described in greater detail with reference to FIGS. 4 and 5.

The laser diode 22 comprises at least two active regions 24 stacked on one another in the emission direction E. Each active region 24, also called p-n junction or quantum well junction, participates in the laser radiation emitted by the laser diode 22. The stack of active regions 24 extends between reflective mirrors 26, 28 extending on either side of the stack of active regions 24 and between a cathode 30 and an anode 32 extending on either side of the reflective mirrors 26, 28. In other words, in the stacking direction E, the laser diode successively comprises a cathode 30, a lower reflective mirror 26, the stack of at least two active regions 24, an upper reflective mirror 28 and an anode 32. Furthermore, a substrate 34 extends, for example, between the cathode 30 and the lower reflective mirror 26. The various elements of the laser diode 22 extend substantially perpendicular to the emission direction E and are therefore substantially parallel to the upper face 12 of the support 10 on which the laser diode 22 is disposed.

The lower reflective mirror 26 is, for example, a Bragg mirror formed of an n-doped material (also known by the term n DBR) and the upper reflective mirror 28 is, for example, a Bragg mirror formed of a p-doped material (also known by the term p DBR). These Bragg mirrors 26, 28 are formed of a plurality of layers having alternately a high refractive index and a low refractive index. According to one embodiment, the layers are formed alternately of gallium arsenide (GaAs) and aluminum gallium arsenide (GaAlAs). Such mirrors 26, 28 around the stack of active regions 24 form a laser resonator arranged to amplify the laser radiation emitted by the active regions 24.

An opening 36 is formed in the anode 32, through which the laser beam emitted by the laser diode 22 passes. This opening 36, called active opening, extends substantially parallel to the external face 12 of the support 10. The active opening 36 has, for example, a diameter substantially between 5 μm and 25 μm. According to one embodiment, the diameter of the active opening 36 is close to 7 μm, and this makes it possible to have a size of the laser diode 22 that is appropriate for placing the desired number of laser diodes 22 per laser chip 14, while at the same time maintaining an acceptable size of laser chip 14.

By making a current circulate between the cathode 30 and the anode 32, the active regions 24 of the laser diode 22 emit laser radiation that is amplified by the lower and upper reflective mirrors 26, 28 and that is emitted in the emission direction E toward the outside of the laser diode 22, passing through the active opening 36. Such a laser diode 22 is known as a vertical cavity surface emitting laser or VCSEL diode and has the particular feature of having a plurality of active regions while such diodes with a single active region are normally used. The equivalent electrical circuit of such a laser diode 22 is depicted in FIG. 5. The stack of active regions 24 corresponds to light-emitting diodes 38 in series between which tunnel diodes 40 are arranged. Each reflective mirror 26, 28 corresponds to a resistor 42, disposed in series on each side of the light-emitting diodes 38. The cathode 30 corresponds to the ground 44 connected in series to a resistor 42 and the anode 32 corresponds to a connection terminal 46 connected in series to the other resistor 42.

According to one embodiment, each laser diode 22 comprises three active regions 24 extending between the reflective mirrors 26, 28, and this makes it possible to obtain particularly satisfactory performance, as will be described below.

When the laser chips 14 are installed on the support 10, the cathodes 30 of the laser diodes 22 of this laser chip 14 extend on the side of the external face 12 of the support 10 and the anodes 32 extend on the side of the outside of the laser chip 14 such that the laser radiation is emitted toward the preforms 2, as described above.

The supply of electrical power to the laser diodes 22 is ensured by way of electrical connections 48 connected to the cathodes 30 and electrical connections 50 connected to the anodes 32, as depicted in FIGS. 2 and 3.

The use of vertical cavity surface emitting laser diodes 22 comprising a plurality of active regions in the context of a laser emitter 4 of a heating station 1 has a number of advantages.

Compared with laser diodes with a single active region and equivalent performance, the use of laser diodes with a plurality of active regions makes it possible to reduce the number of laser chips 14 per laser emitter 4 and thus to simplify the assembly and the connections of the laser emitter 4, as can be seen by comparing FIGS. 2 and 6. More particularly, the operations of cutting the laser chips 14 and placing the laser chips 14 on the support 10 are reduced, as are the operations of electrical connection (or “wire bonding”). This can be seen by comparing FIG. 3 and FIG. 7, which depicts a laser emitter according to the prior art. Indeed, as can be seen in FIG. 7, a greater number of electrical connections 50 is necessary to supply power to the various laser diodes 22 compared with the laser emitter depicted in FIG. 3. In FIG. 7, the numerical references identical to those in FIG. 3 denote the same elements.

As a variant, by keeping the same number of laser chips 14, better performance can be obtained for a laser emitter 4 comprising laser diodes 22 with a plurality of active regions 24.

Furthermore, the voltage across the terminals of each laser diode 22 with a plurality of active regions 24 is greater than the voltage required to supply power to laser diodes with a single active region. Thus, for the same supply power, the intensity of the current supplying the laser diodes 22 is reduced, the power being the product of the voltage and the intensity. This decrease in intensity makes it possible to reduce the electrical losses through the Joule effect in the heating station 1. Thus, the electric current supplying the laser chips 14 has an intensity substantially less than or equal to 10 A, preferably less than or equal to 8 A. Laser diodes 22 with three active regions 24 are particularly advantageous for obtaining this result since they make it possible to decrease the intensity while at the same time maintaining an equivalent efficiency. An optimum number of active regions is defined depending on the materials constituting the laser diodes 22, beyond which the efficiency may decrease.

Furthermore, this higher voltage also makes it possible to improve the control of the laser radiation by monitoring the voltage across the terminals of the emitter. This voltage is measured at the end of the power supply cables connected to the emitter, taking into account the impedance of the cables. However, since the impedance of the cables is not known, it is calculated as a function of the intensity, and this can lead to errors due to voltage drops in the cables that increase with the intensity of the current in these cables. As the voltage across the terminals of the diodes is higher, the intensity of the current in the cables is lower for the same power. Thus, the decrease in voltage causes a decrease in the voltage drops and therefore a reduction in the error in determining the voltage across the terminals of the emitters 4 while the voltage is measured at the end of the power supply cables. The reduction of the relative error related to these voltage drops thus makes it possible to improve the control of the correct operation of the laser emitter 4.

A current of lower intensity also makes it possible to increase the lifetime of the components of the laser emitter 4, and in particular of the laser chips 14. In addition, by operating at a reduced intensity, the components for controlling the laser emitters 4 can have a lower cost and the power supply cables can have a smaller section, and this reduces the costs of implementing the heating station 1.

1. A heating station of a container manufacturing installation, said heating station having a plurality of laser emitters, each laser emitter comprising a plurality of laser chips mounted on an external face of at least one support, each laser chip comprising at least one laser diode arranged to emit laser radiation in the infrared range in an emission direction substantially perpendicular to the external face of the support, characterized in that each laser diode comprises at least two active regions stacked on one another in the emission direction, each active region participating in the laser radiation emitted by said laser diode.

2. The heating station as claimed in claim 1, wherein each laser diode is a vertical cavity surface emitting laser diode, each active region being a quantum well junction extending in a direction substantially perpendicular to the emission direction- and substantially parallel to the external face of the support.

3. The heating station as claimed in claim 1, wherein the laser radiation is emitted through an active opening of each laser diode, said active opening extending substantially parallel to the external face of the support and having a diameter substantially between 5 μm and 25 μm.

4. The heating station as claimed in claim 1, wherein the laser radiation emitted by each laser diode has a wavelength substantially between 1120 nm and 1140 nm.

5. The heating station as claimed in claim 1, wherein each laser diode comprises three active regions stacked on one another in the emission direction, each active region participating in the laser radiation emitted by said laser diode.

6. The heating station as claimed in claim 1, wherein each laser chip has an irradiation optical power density substantially between 1 and 20 W·mm⁻².

7. The heating station as claimed in claim 1, comprising between five and sixty laser chips, said laser chips being arranged in at least one row comprising a plurality of laser chips that are adjacent to one another in a longitudinal direction substantially perpendicular to the emission direction.

8. The heating station as claimed in claim 1, comprising a cooling device arranged on an inner face of the support, which is opposite the external face of the support, said support being made from a material that is thermally conductive, so as to allow the laser chips to be cooled by the cooling device, and electrically insulating.

9. The heating station as claimed in claim 1, wherein the laser chips are supplied with electric current, said electric current having an intensity substantially less than or equal to 10 A, preferably less than or equal to 8 A.

10. A container manufacturing installation having a heating station comprising a plurality of laser emitters as claimed in claim 1, said laser emitters being distributed in an elevation direction corresponding to the height of preforms intended to be formed into containers in the manufacturing installation and in a longitudinal direction corresponding to a direction of travel of the preforms through the heating station facing the laser emitters.

11. A container manufacturing installation comprising a heating station, the heating station comprising a plurality of laser emitters, each laser emitter comprising a plurality of laser chips mounted on an external face of at least one support, each laser chip comprising at least one laser diode arranged to emit laser radiation in the infrared range in an emission direction, the emission direction being substantially perpendicular to the external face of the support, wherein each laser diode comprises at least two active regions stacked on one another in the emission direction, wherein each active region participates in the laser radiation emitted by said laser diode.

12. A heating station of a container manufacturing installation, said heating station comprising a plurality of laser emitters, each laser emitter comprising a plurality of laser chips mounted on an outer face of at least one support, each laser chip comprising at least one laser diode arranged to emit laser radiation in the infrared range in an emission direction, the emission direction being perpendicular to the external face of the support, characterized in that each laser diode comprises at least two active regions stacked on one another in the emission direction, each active region participates in the laser radiation emitted by the laser diode.
